(19) United States
(12) Patent Application Publication
(10) Pub. No.: US 2012/0188004 A1
(43) Pub. Date: Jul. 26, 2012

(54) Housing For An Inertial Switch

(76) Inventor: Benjamin Slotznick, Mt. Gretna, PA (US)

(21) Appl. No.: 13/357,957

(22) Filed: Jan. 25, 2012

Related U.S. Application Data
(60) Provisional application No. 61/436,308, filed on Jan. 26, 2011.

(51) Int. Cl. H03K 17/965

(52) U.S. Cl. 327/517

(57) ABSTRACT

An apparatus that provides switch signals includes an upper portion, a lower portion, compressible material disposed between the upper portion and the lower portion, memory and a processor. The upper portion includes an outer surface having portions that define at least two different regions. At least one of the different regions has a switch function. The upper portion also includes a three-dimensional orientation sensor that generates three-dimensional orientation signals in response to movement of the upper portion. The lower portion has a bottom surface adapted to be placed against an immovable surface. The memory electronically stores information regarding the portions of the outer surface that define at least one region having a switch function. The processor includes processor logic that uses the electronically stored information in the memory and the orientation signals to detect whether a region having a switch function was pressed, and if so, outputs a switch signal.

### CROSS-REFERENCE TO RELATED APPLICATION

This application claims the benefit of U.S. Provisional Patent Application No. 61/436,308 filed Jan. 26, 2011, which is incorporated in its entirety herein.

### BACKGROUND OF THE INVENTION

Many devices include components which sense a change in their orientation with respect to gravity and inertia. These components have many names and methods of construction. Names include gyroscopes, accelerometers, inclinators, and tilt sensors. The methods include mechanical gyroscopic devices, electronic sensors, piezoelectric sensors, capacitive sensors, microelectromechanical systems (MEMS), arrays of force sensing transducers (including force sensing resistors), and even nanodevices. The term “accelerometer” as used herein refers generically to any one of these devices (even if not a true accelerometer), without limitation as to specific technology and methodology used. In this disclosure, the term “orientation sensor” is used to refer to a sensor or device which uses a generic accelerometer (or accelerometers) to detect a change in orientation with respect to space, gravity, or inertia A “three-dimensional orientation sensor” can detect change of orientation with respect to all three dimensions, and may consist of one 3-D accelerometer, or it may contain an array of accelerometers which together detect change with respect to all three dimensions. Accelerometers are also used to measure vibration, vibration shock, falling, seismic activity, inclination, machine vibration, dynamic distance and speed with or without the influence of gravity.

Accelerometers are increasingly being incorporated into personal electronic devices, including many smart phones, digital audio players, personal digital assistances, video game controllers, tablet PCs, digital cameras and camcorders. Uses are many and expanding. For example, digital cameras and camcorders use accelerometers for anti-blur capturing and image stabilization. Many devices (such as some tablet PCs, smart phones and digital cameras) use accelerometers to switch a display screen from landscape to portrait mode, depending upon how the device is held. Motion and tilt are used as controlling actions for video games, whether played on a dedicated game machine, on a tablet PC, or on a smart phone. Some devices use accelerometers for step recognition (and counting) in sport applications (i.e., as an electronic pedometer).

Some devices contain more than one accelerometer, particularly if the accelerometer is measuring movement with respect to more than one axis. However, in this disclosure, the term “accelerometer” is used to refer both individually and collectively to any and all the accelerometers within a device.

Causing movement in a device, such as by pushing on it or tapping it can be detected by an accelerometer. However, though the terms “push” and “tap” are often used interchangeably in ordinary conversation, it is important to clarify the difference. A “tap” is a light striking action that combines a pressing action and a releasing action both of which occur within a short time period. Some sensor arrays are engineered to treat a “tap” as a unitary event, in the same way that a mouse click event (with respect to a button on a computer mouse) comprises both the press and release of the mouse button—and these sensors are sometimes called “tap sensors.” Other sensors may be able to distinguish between the press and release aspects of a tap, in the same way that the button on a computer mouse can have a mouse down and a mouse up event.

Importantly for this disclosure, accelerometers permit tap gestures to be used for controlling applications such as a music player or sport application. For example, the Nokia® 5500 smartphone, incorporates a 3D accelerometer and a music player. When the Nokia 5500 is in a user's pocket, the user can forward the music player to the next song by tapping the device through his or her clothing.

However all current uses expect (and require) that the accelerometer has free-movement along the axis on which movement is intended to be detected. For example, a device in a pocket is not resting against an immovable object, so the device (and the accelerometer inside it) will still obviously move when pushed or tapped, even if the tap originates outside the pocket. In contrast, tapping or pushing down on a solid device that rests on a hard surface (such as a table or desk), would not be expected to elicit a change in an accelerometer built into the device, so that tapping or pushing down on the device could not be coupled with the accelerometer as a switch for device functions.

U.S. Patent Application Publication No. 2010/0060604 (Zwart et al.) discloses the use of accelerometers (and similar detectors) to determine when a person taps at a pre-specified location on the surface of an object, and the use of that determination as an input, trigger or location on the surface of an object, and the use of that determination as an input, trigger or switching event. The tap can be by finger, finger nail, stylus, credit card, or other object. The tap creates an impulse, vibration, or acoustic type wave in the material which forms the surface being tapped. The accelerometers detect this vibration or wave, including amplitude over time, to determine the location of the tap in a similar manner to how several seismographs can determine the location of an earthquake. In this way, the accelerometers in Zwart et al. determine the existence of a tap on the surface, and where on that surface the tap occurred. The readings of the accelerometers provide signatures for different tap events over the surface. If a tap is detected as occurring at a designated location—that is, the tap produces the pre-assigned or pre-recorded signature of the tap event by the various accelerometers—then the Zwart et al. device records this as a tap event at that location, and can use that occurrence to trigger a switch. Otherwise, the Zwart et al. device shows no input as occurring. Zwart et al. only detect a tap as a unitary event.

Only some of the interactions with a surface will produce taps or impulses which Zwart et al. can detect. Zwart et al. does not disclose how to detect when one object is very near the surface of another object, or gently touching the surface, or gently swiping along a surface. Zwart et al. also does not disclose how to detect when one object (which has been near or gently touching another object) moves away from that second object. Capacitive sensors (such as touch screens) can do that. Zwart et al. also does not disclose how to detect when one object gently, though possibly with great force, pushes on the surface of another object—or then releases that force.

U.S. Patent Application Publication No. 2007/0247434 (Cradick et al.) also discloses methods of detecting and locating taps on a surface, and mentions that various types of tap sensors, including ones with accelerometers, can be used to detect those taps. Cradick et al. only discloses methods of detecting a tap as a unitary event. Cradick et al. relies on the property that the reaction sensed by an individual tap sensor varies with distance from the tap. In a generally planar surface, Cradick et al require three tap sensors for triangulation purposes.

Both Zwart et al. and Cradick et al. can detect a tap striking a surface by using an accelerometer. Both treat a tap as a unitary event. As mentioned above, this event can be likened to a mouse click. However, consider using a computer mouse for a drag and drop operation. The user presses down on the mouse button, then while keeping the button down, moves the mouse to the desired location, then releases the mouse button. Pressing on the mouse button and later releasing it are two distinct events. Two different kinds of switching events are required of many control devices, and thus unitary event detection has inherent limitations. Furthermore, the unitary event detection in Zwart et al. and Cradick et al. fails to capture more granular information, such as where on a surface did the user tap (e.g., left or right side, center or corner).

European Patent Application EP 2315101 A1 (Holbein et al.) discloses how to use an accelerometer (and/or force sensors such as piezo-electric devices or force resistors) to turn the touch-screen of a hand held electronic device into one large button-switch, which when pushed, wakes up the device. Holbein et al. discloses only how to use the inertial event detected by the accelerometer (and/or force events detected by the force sensors) to determine that a unitary tap (or press down) event has occurred. Holbein et al. does not disclose what inertial event (if any) will be caused by the release of pressure, or how that event will be affected by the fact that the user may be holding the device in his or her hand, which will react to the release in pressure with motion of its own.

Preferred embodiments of the present invention use one 3-D accelerometer (or other means of detecting change of spatial orientation) to determine when a person presses at a pre-specified location on the surface of an object (including an object with a planar surface), and more specifically, one of at least two pre-specified locations on the surface of an object, and the use of that determination as an input, trigger or switching event. In addition, preferred embodiments of the present invention disclose how to use one 3-D accelerometer (or other means of detecting change of spatial orientation) to determine when a person releases that pressure, and to use that determination as an input, trigger or switching event.

### SUMMARY OF THE INVENTION

The present invention discloses how to construct a device with a solid casing, so that even when the device is placed on an immovable surface, tapping or pushing down on the device is able to trigger the accelerometer, so that a tapping action can be used as a switch to control device functions.

A preferred embodiment incorporates a gasket of compressible material around the outside housing of the device, placed between the portion of the housing that rests on the immovable surface and the rest of the housing to which the accelerometer is attached.

In an alternative embodiment, the gasket comprises that part of the housing that rests on the immovable surface. In another alternative embodiment, the gasket comprises only a portion of the part of the housing that rests on the immovable surface. In some embodiments the gasket is an elastomer.

In another preferred embodiment, a kink, bend, or deformation in the housing circles the outside of the housing of the device, on the sides or along the periphery of the device. This kink, bend, or deformation is placed between the portion of the housing that rests on the immovable surface and the rest of the housing to which the accelerometer is attached. This kink, bend, or deformation introduces flex to that portion of the housing, as is well known in the material fabrication arts, thus enabling movement of the accelerometer inside the device when the device is pushed against the immovable surface.

In alternative embodiments, the kink, bend or deformation has different cross-sections. Alternate embodiments use, multiple kinks, bends, or deformations. Still other alternate embodiments use combinations of kinks, bends, and deformations. Other embodiments use combinations of different kinds, bends and deformations. The kink(s), bend(s), and deformation(s) are functional but to many people appear as a decorative aspect of the housing. In an alternative embodiment, springs or sprung legs are placed on the “bottom” of the device housing, so that when the device is placed upon the immovable surface, it rests on these legs. This enables movement of the accelerometer inside the device when the device is pushed against the immovable surface.

The kink(s), bend(s), and deformation(s) may be constructed of the same or different material as the housing. The kink(s), bend(s), and deformation(s) are compressible, and are referred to generically herein as a “compressible material.”

In an alternative embodiment, the gasket, kink, bend, or deformation is not around the sides of the device, but is on the top of the device separating the pushable (or tappable) portion of the top of the device (to which the accelerometer is attached) from the rest of the device.

In an alternative embodiment, a significant portion of the body of the device is composed of one or more materials that have sufficient flex, so that pushing or tapping on the top of the device will set up a vibration or vibrations that are recorded by the accelerometer.

In these various embodiments, when pushing the device against the immovable surface, if the device is not pushed squarely on its inertial center, the different parts of the device will not move uniformly towards the immovable object. Analysis of this differential movement using the output of the accelerometers enables the device to act as several different switches, depending which part of the device is pressed. For example, pressing on the left front corner of a device will cause the accelerometers to give different output than pressing on the right back corner of the device.

In these various embodiments the accelerometer (or accompanying circuitry or software) can be designed to register the action of pressing-a-portion-of-the-device as a switching action. Alternatively the accelerometer (or accompanying circuitry or software) can be designed to register the action of releasing-the-device (after the pressing-a-portion-of-the-device has occurred) as a switching action. Alternatively it can be designed such that a tap (combined pressing and releasing action that occurs in a short time) is the switching action. In an alternative embodiment, a double tap (or other multiple tap) is the switching action.

This invention also teaches methods of constructing an auxiliary housing, that fits around a device with an accelerometer, in the same way that a cell phone case fits around a cell phone, or a case fits around an iPod. By this method using this embodiment, devices with accelerometers that do not incorporate this invention can obtain the benefits of this invention by slipping them into cases which embody this invention.

In still another alternative embodiment, the accelerometer is built into the auxiliary housing, along a means of transmitting the output of the accelerometer to the device encased in the auxiliary housing. By this method, devices without accelerometers can obtain the benefits of accelerometers as well as the benefits of this invention by slipping these devices into cases which embody this invention.

### BRIEF DESCRIPTION OF THE DRAWINGS

The foregoing summary as well as the following detailed description of preferred embodiments of the invention, will be better understood when read in conjunction with the appended drawings. For the purpose of illustrating the invention, the drawings show presently preferred embodiments. However, the invention is not limited to the precise arrangements and instrumentalities shown. In the drawings:

FIG. 1A shows the cross-section of a device housed in a rigid casing, and does not illustrate any embodiments of the present invention.

FIG. 1B shows the cross-section of a similar device, but with a gasket of compressible material separating the bottom of the device from the portion of the housing to which the accelerometer is attached, in accordance with one preferred embodiment of the present invention.

FIG. 2A shows the cross-section of the device pictured in FIG. 1A resting on an immovable flat surface.

FIG. 2B shows the cross-section of the device pictured in FIG. 2A being pushed down against the immovable flat surface.

FIG. 3A shows the cross-section of the device pictured in FIG. 1B resting on an immovable flat surface.

FIG. 3B shows the cross-section of the device pictured in FIG. 3A being pushed straight down against the immovable flat surface.

FIG. 4A shows the cross-section of the device pictured in FIG. 3A with one side of its top being pushed down against the immovable flat surface.

FIG. 4B shows the cross-section of the device pictured in FIG. 3A with the other side of its top being pushed down against the immovable flat surface.

FIG. 5A shows the cross-section of a device similar to the device pictured in FIG. 1B, but with a kink in the casing rather than a gasket, in accordance with another preferred embodiment of the present invention.

FIG. 5B shows the cross-section of a device similar to the device pictured in FIG. 1A, but with the addition of sprung legs, in accordance with another preferred embodiment of the present invention.

FIG. 5C shows the cross-section of a device similar to the device pictured in FIG. 5A, but with a compound bend in the casing rather than a kink, in accordance with another preferred embodiment of the present invention.

FIG. 5D shows the cross-section of a device similar to the device pictured in FIG. 5B, but with a compressible gasket at the bottom of the casing rather than sprung legs, in accordance with another preferred embodiment of the present invention.

FIG. 6A shows the cross-section of a device similar to FIG. 5C, but with a compound bend incorporated into the top of the casing rather than its sides, in accordance with another preferred embodiment of the present invention.

FIG. 6B shows the cross-section of a device similar to FIG. 1A, but using materials in the housing with sufficient flex as to allow tapping to create vibration, in accordance with another preferred embodiment of the present invention.

FIG. 7 shows a three-dimensional view of the device shown in FIG. 1B.

FIG. 8 shows the same three-dimensional view of the device shown in FIG. 7, except with nine areas on the top of the device delineated as virtual buttons. Pushing on each area will elicit a recognizable and distinct output from the accelerometer.

FIG. 9 shows the same three-dimensional view of the device shown in FIG. 7, except with four areas on the top of the device delineated as virtual buttons. Pushing on each area will elicit a recognizable and distinct output from the accelerometer.

FIG. 10 shows a three-dimensional view with cross-section of an auxiliary housing that embodies one preferred embodiment of the present invention, into which has been slipped a device (such as a conventional cell phone) which has an accelerometer but which does not embody the present invention.

FIG. 11 is a flow chart in accordance with another preferred embodiment of the present invention.

FIG. 12 is a schematic hardware view of one preferred embodiment of the present invention.

FIG. 13 is a flow chart in accordance with another preferred embodiment of the present invention.

FIGS. 14A-14D illustrate additional details regarding the embodiments of the present invention shown in FIG. 3A, FIG. 5A, FIG. 5C, and FIG. 10, respectively.

### DETAILED DESCRIPTION OF THE INVENTION

Certain terminology is used herein for convenience only and is not to be taken as a limitation on the present invention.

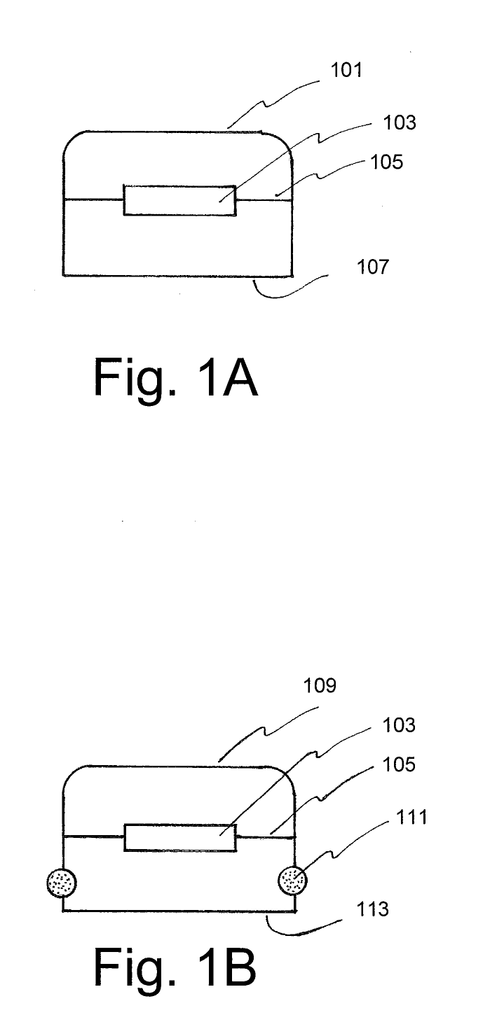

FIG. 1A is a cross-section of a device that incorporates an accelerometer, but does not embody this invention. It is most easy to visualize this figure as representing a cellular telephone or an MP3 player. However similar figures with the same components, but at different scales could be drawn to represent other devices with accelerometers. The device has a rigid casing or housing 101. If you set it down on a table, a portion of the casing 107 would be the part placed against the table. In this figure one thinks of 107 as the bottom of the device, but that would be as accurate in a similar figure in which 107 is not a straight line. The device also includes an accelerometer 103 which is attached at 105 to the housing so that movements in the housing would move, affect, and register with the accelerometer.

In contrast to FIG. 1A, FIG. 1B is a cross-section of a device that embodies one preferred embodiment of the present invention. It has a housing that consists of a rigid top part 109 and a rigid part that would rest against a table if it were placed thereon (the “bottom” 113), which correspond respectively to 101 and 107 of FIG. 1A. The device in FIG. 1B also has an accelerometer 103 that is attached at 105 to the top portion of the device 109. However in FIG. 1B, the top of the device 109 is separated from the bottom of the device 113 by a gasket 111. The gasket 111 is shown with a circular cross-section, but other embodiments use gaskets with different cross-sections. As is well known to artisans in gasket making and material fabrication, there are a variety of ways to attach the gasket 111 to the housing at 105, not shown in detail in FIG. 1B. Different embodiments will use different methods.

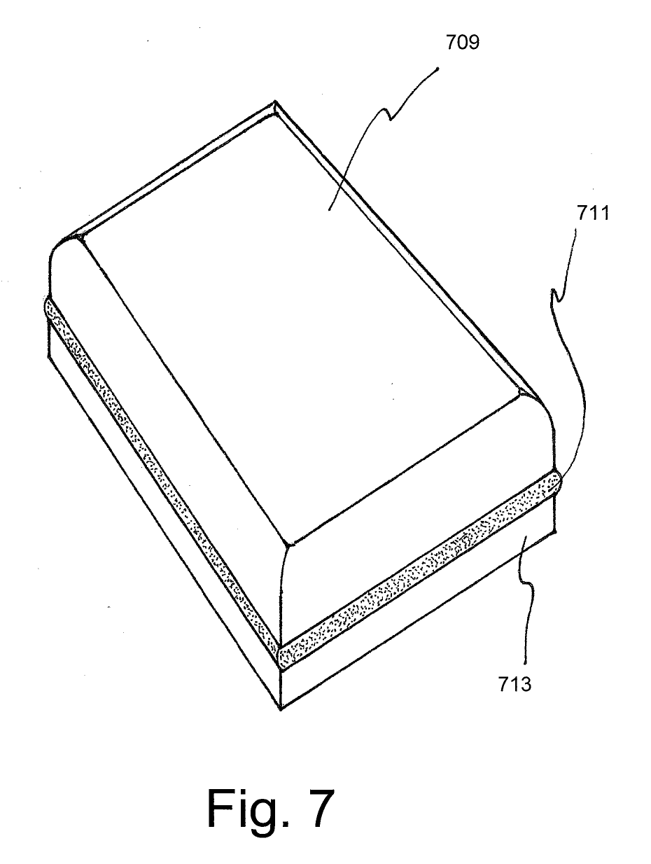

FIG. 7 shows a three-dimensional view of the outside of a device with a cross-section as shown in FIG. 1B. The rigid housing labeled 109 in FIG. 1B is shown as 709 in FIG. 7. The gasket labeled 111 in FIG. 1B is shown as 711 in FIG. 7. The side of the device which is shown in FIG. 1B as attached to the bottom 113 is shown as 713 in FIG. 7. In both figures, the gasket separates the top of the device from the bottom of the device.

A three-dimensional view of the outside of the device pictured in FIG. 1A is similar to FIG. 7, but without a gasket.

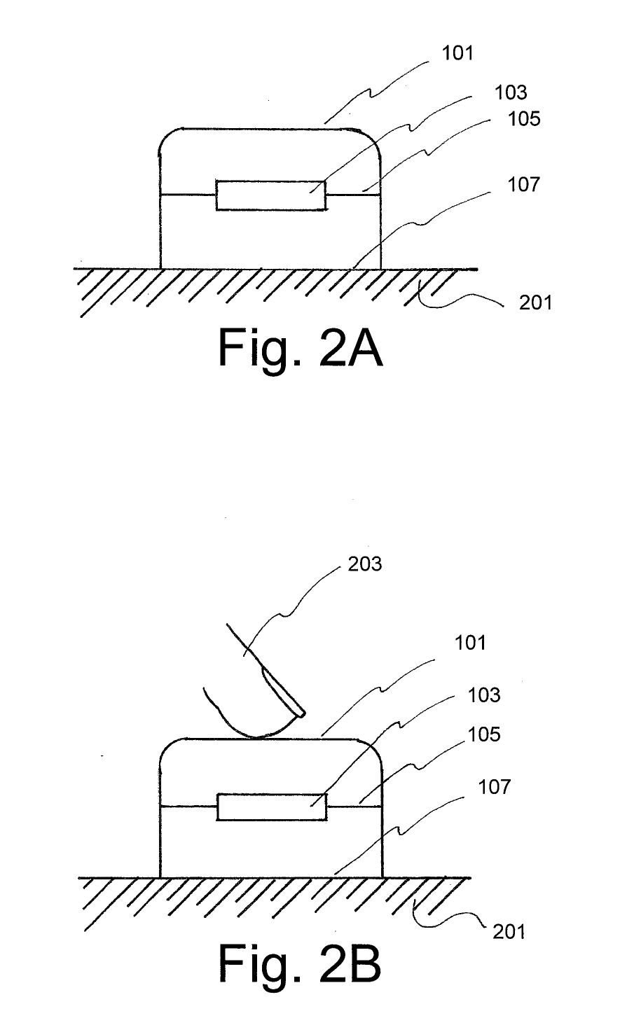

FIG. 2A shows the same device pictured in FIG. 1A, again in cross-section. However, in FIG. 2A the device is resting on an immovable surface 201, or more specifically, the bottom of the device 107 is resting on an immovable surface 201. This is a device that incorporates an accelerometer 103 attached at 105 to its housing 109, but does not embody the present invention. FIG. 2B illustrates what happens when a finger 203 pushes down on the device illustrated in FIG. 2A, which is a device that does not embody the invention. Because the surface 201 is immovable, and because the housing of the device 101 is rigid, nothing happens. There is no movement for the accelerometer 103 to detect. Neither the device, nor the accelerometer 103 that is an integral part of the device (attached at 105 to the inside of the device) is able to move as long as the housing maintains structural integrity and does not break.

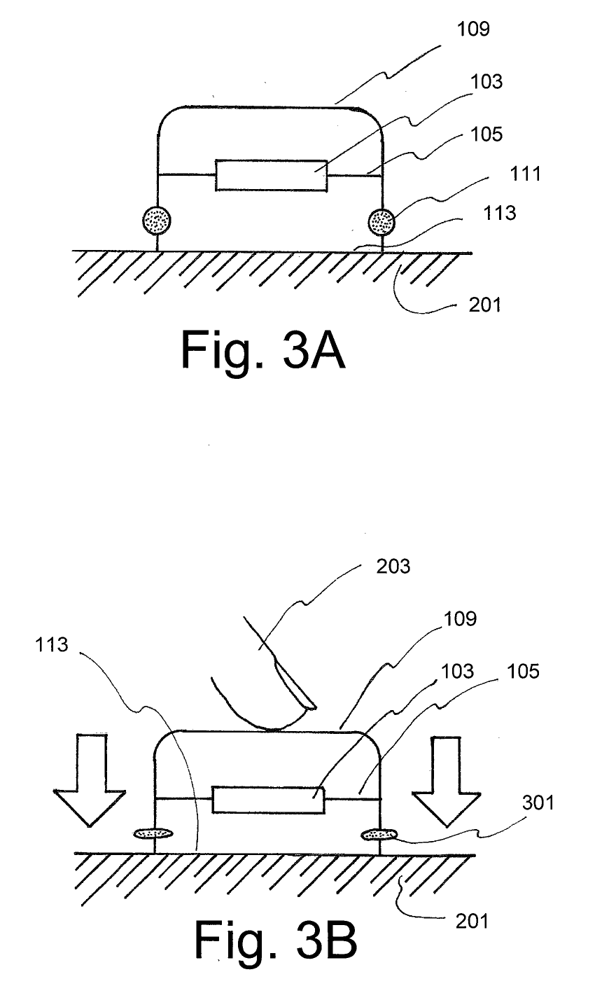

FIG. 3A and FIG. 3B show similar views as FIG. 2A and FIG. 2B. However the device shown in figures FIG. 3A and FIG. 3B embodies the invention, whereas the device shown in figures FIG. 2A and FIG. 2B does not.

FIG. 3A shows the same cross-section of the device pictured in FIG. 1B. However in this figure, the device is resting on an immovable surface 201, or more specifically, the bottom of the device 113 is resting on an immovable surface 201. This is a device that incorporates an accelerometer 103 attached at 105 to its housing 109. Unlike the device pictured in FIG. 1A and FIG. 2A, this device is one of the preferred embodiments of the present invention and incorporates a compressible gasket 111.

FIG. 3B illustrates what happens when a finger 203 pushes down on the device illustrated in FIG. 3A. In FIG. 3B, the finger is pushing straight down on the center of the device. The gasket pictured in FIG. 3A is 111 is compressible.

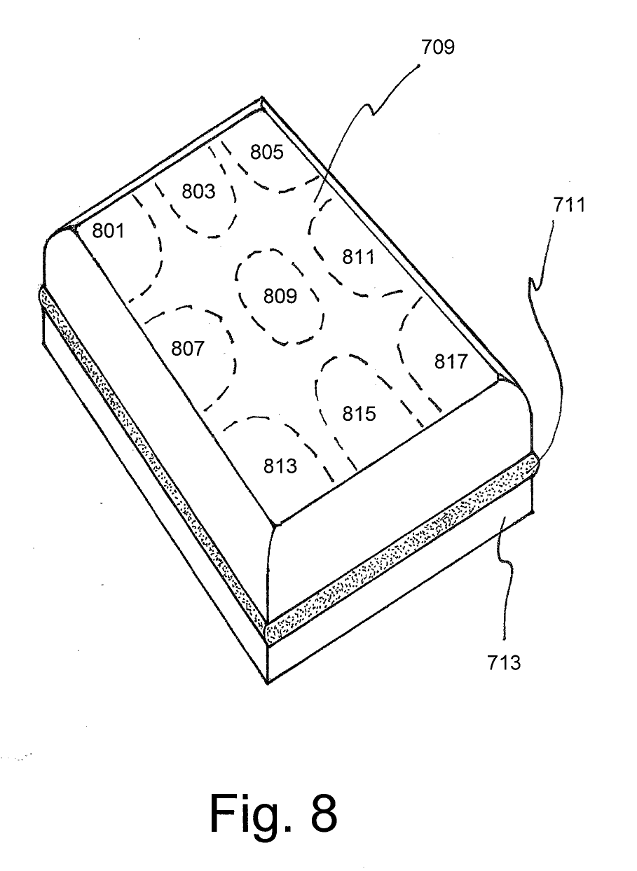

For a three-dimensional view, FIG. 8 shows a finger pressing on the center of the top of the device 709 in the very center of that top 809.

Returning to FIG. 3B, when the finger 203 pushes straight down on the top of the rigid housing 109, the force of the finger compresses the gasket 301. This occurs, because the surface 201 that the device is resting on is immovable, and consequently the rigid bottom of the device 113, and the sides attached to it, are also immovable. As a consequence, several objects move downward: the finger 203, the top portion of the device housing 109, items attached to this portion of the device housing at 105, and the accelerometer 103. The accelerometer 103 senses this movement which can then be used as a triggering action to control or switch other device functions.

As is well known to artisans in gasket construction, gaskets are constructed of materials with sufficient resiliency, that when the pressure exerted on them is released, they will spring back. (The amount of spring back varies with material construction.) In the preferred embodiment pictured, the gasket is constructed of an elastomer that springs back to its original shape, given the expected pressures encountered.

Returning now to FIG. 3B, when the finger 203 is withdrawn from the device, the gasket 301 springs back to the shape shown as 111 in FIG. 3A, and the device as well resumes the shape shown in FIG. 3A. During this resumption in shape, the device housing 109 moves upward, along with items attached to this portion of the device at 105, including the accelerometer 103. The accelerometer 103 senses this movement which can be used as a triggering action to control or switch other device functions.

As is well known in the art of controls and switching functions, the downward movement as sensed by the accelerometer can be used as a control triggering action, the upward movement as sensed by the accelerometer can be used as a control triggering action, and some combination of the two (with or without contingent timing parameters) can be used as a control triggering action. Repetition (as with double-clicks on a computer mouse) can also be used as a control triggering action.

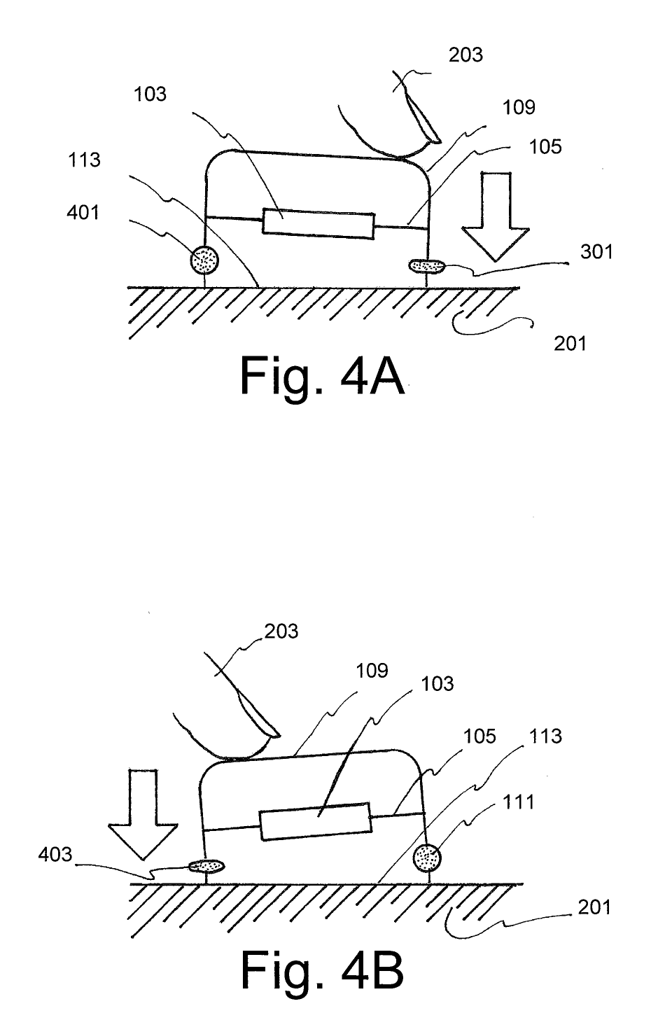

FIG. 4A shows the same device shown in FIG. 3A and FIG. 3B. However, here the finger, 203 is not pressing on the center of the top of the device 109 but rather is pressing to one side of the top (the right side in relationship to the illustration). In three-dimensional terms, this is the area labeled 811 in FIG. 8. When the finger is pressed down, it does not exert a uniform pressure on all parts of the gasket (713 in FIGS. 8, and 401 and 301 in FIG. 4A). Because of the immovable surface 201 on which the rigid bottom of the device 113 is resting, some parts of the gasket are compressed, as shown by 301 in FIG. 4A. Other parts of the gasket are not compressed (or compressed to a lesser extent), as shown by 401 in FIG. 4A.

The orientation of the accelerometer 103, has changed because it is attached at 105 to the rigid housing 109. The orientation is different in FIG. 4A, than in FIG. 3A or FIG. 3B.

By methods well known to those in the field of accelerometers, the registered change in orientation of the device from FIG. 3A to FIG. 4A can be detected and used as a triggering action to control or switch device functions, and importantly, this triggering action is distinguishable from the change in orientation from FIG. 3A to FIG. 3B.

When the finger 203 is withdrawn from the device, both gaskets 301 and 401 spring back to the shape shown as 401 in FIG. 4A and 111 in FIG. 3A, and the device as well resumes the shape shown in FIG. 3A. During this resumption in shape, the device housing 109 moves upward, along with items attached to this portion of the device at 105 including the accelerometer 103. The accelerometer 103 senses this movement which can be used as a triggering action to control or switch other device functions.

As is well known in the art of controls and switching functions, the downward movement as sensed by the accelerometer can be used as a control triggering action, the upward movement as sensed by the accelerometer can be used as a control triggering action, and some combination of the two (with or without contingent timing parameters) can be used as a control triggering action. Repetition (as with double-clicks on a computer mouse) can also be used as a control triggering action.

The change in orientations from FIG. 3A to FIG. 4A and back, is different than the change in orientations from FIG. 3A to FIG. 3B and back, so that these differing changes in orientations can be used as different switches.

Similarly, FIG. 4B shows the same device shown in FIG. 3A, FIG. 3B, and FIG. 4A. However, here the finger 203 is not pressing on the center of the top of the device 109 but rather to one side of the top (the left side in relationship to the illustration). In three-dimensional terms, this is the area labeled 807 in FIG. 8. When the finger is pressed down, it does not exert a uniform pressure on all parts of the gasket (713 in FIGS. 8, and 403 and 111 in FIG. 4B). Because of the immovable surface 201 on which the rigid bottom of the device 113 is resting, some parts of the gasket are compressed, as shown by 403 in FIG. 4B. Other parts of the gasket are not compressed (or compressed to a lesser extent), as shown by 111 in FIG. 4B.

The orientation of the accelerometer 103 has changed because it is attached at 105 to the rigid housing 109. The orientation is different in FIG. 4B than in FIG. 3A , FIG. 3B, or FIG. 4A.

By methods well know to artisans in the field of accelerometers, the registered change in orientation of the device from FIG. 3A to FIG. 4B can be detected and used as a triggering action to control or switch device functions. This triggering action is distinguishable from the change in orientation from FIG. 3A to FIG. 3B, and from FIG. 3A to FIG. 4A.

In addition, when the finger 203 is withdrawn from the device, both gaskets 111 and 403, spring back to the shape shown as 111 in FIG. 3A, and the device resumes the shape shown in FIG. 3A. During this resumption in shape, the device housing 109 moves upward, along with items attached to this portion of the device at 105, including the accelerometer 103. The accelerometer 103 senses this movement which can be used as a triggering action to control or switch other device functions.

As is well known in the art of controls and switching functions, the downward movement as sensed by the accelerometer can be used as a control triggering action, the upward movement as sensed by the accelerometer can be used as a control triggering action, and some combination of the two (with or without contingent timing parameters) can be used as a control triggering action. Repetition (as with double-clicks on a computer mouse) can also be used as a control triggering action.

The change in orientations from FIG. 3A to FIG. 4B and back, is different than the change in orientations from FIG. 3A to FIG. 3B and back, as well as the change in orientations from FIG. 3A to FIG. 4A and back, so that these differing changes in orientations can be used as different switches.

More generally, a device with an accelerometer (or accelerometers) that can detect changes in orientation along all three dimensions, as shown in FIG. 8, can distinguish between a finger pushing down on the top of the device 709 in the region of 801, versus pushing down in the region of 803, versus pushing down in the region of 805, versus pushing down in the region of 811, versus pushing down in the region of 817, versus pushing down in the region of 815, versus pushing down in the region of 813, versus pushing down in the region of 807, versus pushing down in the center of the top 809.

The areas 801, 803, 805, 807, 809, 811, 813, 815, and 817 are referred to herein as “virtual buttons” because a press or release event can be detected as if the area was a button, even if there is no demarcation on the surface that these areas have such functionality. In general, a “virtual button” is an area on the surface, for which a press or release event can be detected, and which event will be used as pre-specified input for another process. A virtual button may also be outlined, labeled, or demarcated by a change in the surface (such as by a finger sized indentation). Demarcating and labeling a virtual button will make it easier for the user to remember its position and function, but will not affect any technical aspect of the virtual button process. Demarcating and labeling a virtual button may also make it easier for the user to press the correct area of a surface.

More distinct switching areas are possible. However, maintaining reliability depends upon the sensitivity of the accelerometer, the uniformity of compression of the gasket, the balance of the device, the dexterity of the user's fingers, and the programming skill of the designer of the control circuits (or software) that converts registered orientation into signals or commands.

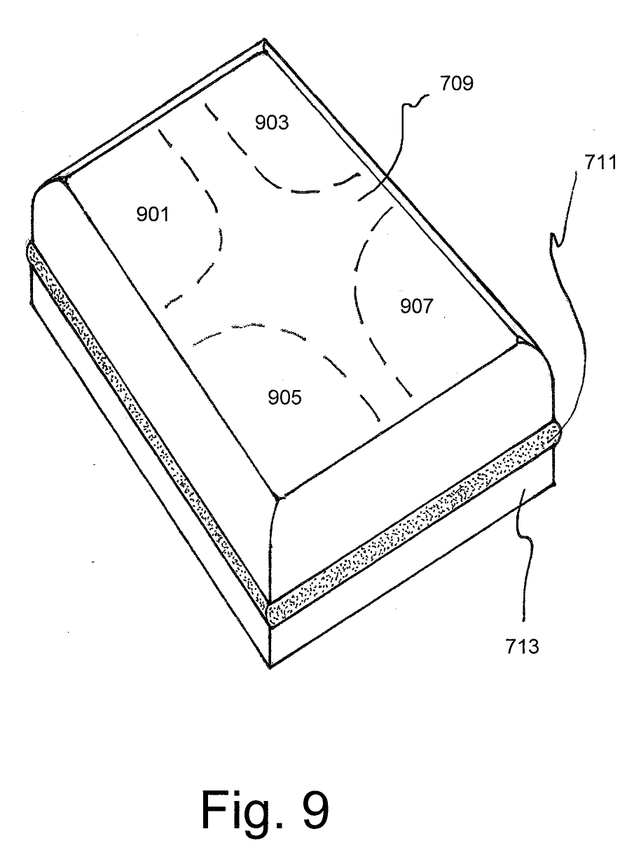

Reliability may be increased by designation (and programming for) fewer distinct switching areas. FIG. 9 shows and example in which only four areas are designated, corresponding to the four corners of the top 709 of the device, namely, the areas labeled 901, 903, 907, and 905. In some applications, such as the creation of mouse-like buttons on the back of a cell phone, only two switches are needed.

In FIG. 9, the areas 901, 903, 905, and 907 are virtual buttons.

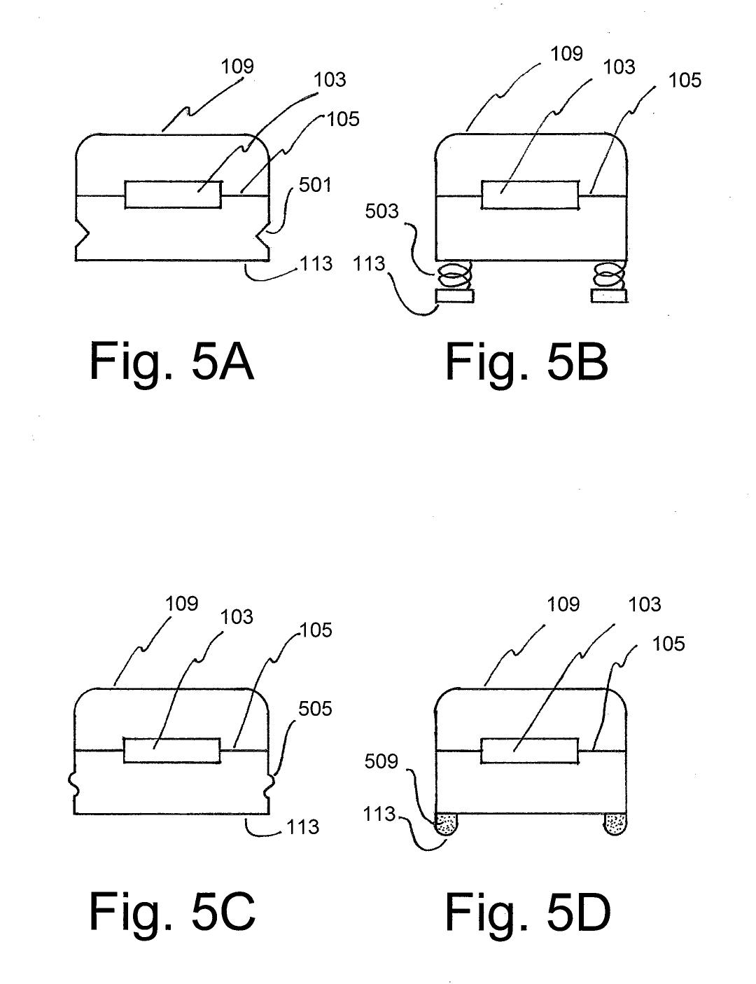

FIG. 5A shows the cross section of a device that is similar to the device in FIG. 1B. The only aspect that differs is that the gasket 111 around the housing (as shown in 109 of FIG. 1B) has been replaced by a kink or crimp 501, in the housing of FIG. 5A. Such accordion-like kinks or crimps are known to introduce flex into an otherwise rigid structure. They are also known to retain a resiliency and to act in a spring-like manner. For this embodiment of the present invention, using methods know to artisans in the field of materials fabrication, these kinks and crimps are designed exhibit the same compression and resiliency as the gaskets 111 shown in FIG. 1B. Consequently, pushing or tapping the device in FIG. 5A can be used to control or switch the device's functionalities in the same manner as pushing or tapping the device in FIG. 1B (as shown in FIG. 3A, FIG. 3B, FIG. 4A, and FIG. 4B).

FIG. 5C shows the cross section of a device that is similar to the device in FIG. 1B. The only aspect that differs is that the gasket 111 around the housing (as shown in 109 in FIG. 1B) has been replaced by a set of compound curves 505 in the housing of FIG. 5C. Such curves are known to introduce flex into an otherwise rigid structure. They are also known to retain a resiliency and to act in a spring-like manner. For this embodiment of the invention, using methods know to artisans in the field of materials fabrication, these kinks and crimps are designed to exhibit the same compression and resiliency as the gaskets 111 shown in FIG. 1B. Consequently, pushing or tapping the device in FIG. 5C can be used to control or switch the device's functionalities in the same manner as pushing or tapping the device in FIG. 1B (as shown in FIG. 3A, FIG. 3B, FIG. 4A, and FIG. 4B).

In alternate embodiments, this compound curve is replaced by a different surface deformation which exhibits the same flexing characteristics.

FIG. 5D shows the cross section of a device that is similar to the device in FIG. 1B. The only aspect that differs is that the gasket has been moved to the bottom of the device so that when the device is set on an immovable surface, the portion of the device resting against the immovable surface (113 of FIG. 5D) is not the housing itself, but rather the gasket 509. The gaskets in the two figures (FIG. 1B and FIG. 5D) have the same compressive and resilient characteristics. Consequently, pushing or tapping the device in FIG. 5D can be used to control or switch the device's functionalities in the same manner as pushing or tapping the device in FIG. 1B (as shown in FIG. 3A, FIG. 3B, FIG. 4A, and FIG. 4B).

FIG. 5D shows a device for which the gasket 509 is continuous along the entire bottom perimeter of the device. In alternate embodiments, the gasket is discontinuous, though retaining the same compressive and resilient properties. In still other embodiments, the gasket is reduced to a set of leg-like protrusions from the bottom, but with the same compressive and resilient properties.

FIG. 5B shows the cross section of a device that is similar to the device in FIG. 5D. The only aspect that differs is that the gasket has been replaced by a surface 113 attached to the housing 109 by springs. The springs (503 in FIG. 5B) have the same compressive and resilient characteristics as the gaskets (509) in FIG. 5D. Consequently, pushing or tapping the device in FIG. 5B can be used to control or switch the device's functionalities in the same manner as pushing or tapping the device in FIG. 1B (as shown in FIG. 3A, FIG. 3B, FIG. 4A, and FIG. 4B).

In a preferred embodiment the surface 113 of FIG. 5B is continuous. In an alternate embodiment it is discontinuous. In still another alternate embodiment, this element is manifest as legs attached by springs, or otherwise sprung legs.

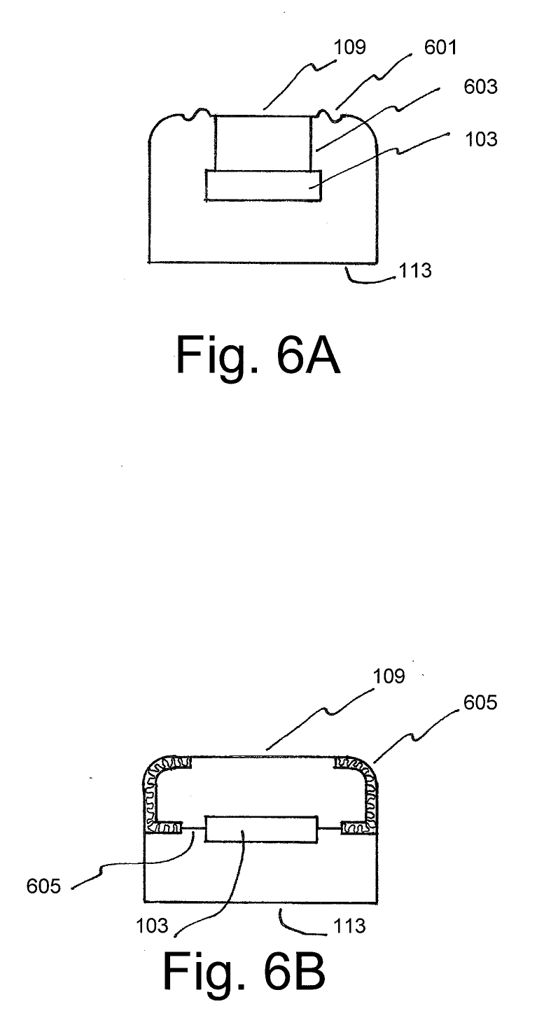

FIG. 6A is in some ways similar to FIG. 5C. It shows the cross section of device with an accelerometer 103 and a rigid housing. The top of the rigid housing 109 is separated from the bottom 113 at some point by a compound curve in the surface of the housing (shown as 505 in FIG. 5C and 601 in FIG. 6A). However, in FIG. 6A, the compound curve is in the top of the housing rather than around the sides. The accelerometer 103 is attached at 603 to the top of the housing (rather than to the side as in detail 105 in FIG. 5C).

In this embodiment, the compound curve allows a finger to push down on the top of the housing as in FIG. 3B. However, it does not allow other different pushes and taps shown in FIG. 4A and FIG. 4B. It can still tell the difference between a finger pushing down on the device, and the finger the withdrawing from the device.

In an alternate embodiment, this compound curve 601 is replaced by a different surface deformation which exhibits the same flexing characteristics. In another alternate embodiment, this compound curve is replaced by a kink, crimp or other deformation such as shown in 501 of FIG. 5A. In another alternative embodiment, this compound curve is replaced by a gasket such as shown in 111 of FIG. 1B.

FIG. 6B shows a device that has a housing that is not rigid everywhere. The top of the housing 109 is rigid, but substantial portions of the sides 605 have sufficient flex that pressing or tapping on the top 10, will transmit vibrations through the sides 605 to the accelerometer 103 through its attachment to the housing at 605. The accelerometer 103 senses and registers the vibration. Using methods known by artisans in the fields of accelerometers and control devices, this vibration of the accelerometer 103 is used to as a triggering action to control or switch device functions. However, pressing the top 109 and releasing it will not necessarily appear as distinct or differing vibration phenomena to the accelerometer 103. On the other hand, for a particularly sensitive accelerometer with special control circuitry, tapping or pushing different regions of the top of the device 109 do appear as distinct vibration phenomena and are used as distinct switch inputs.

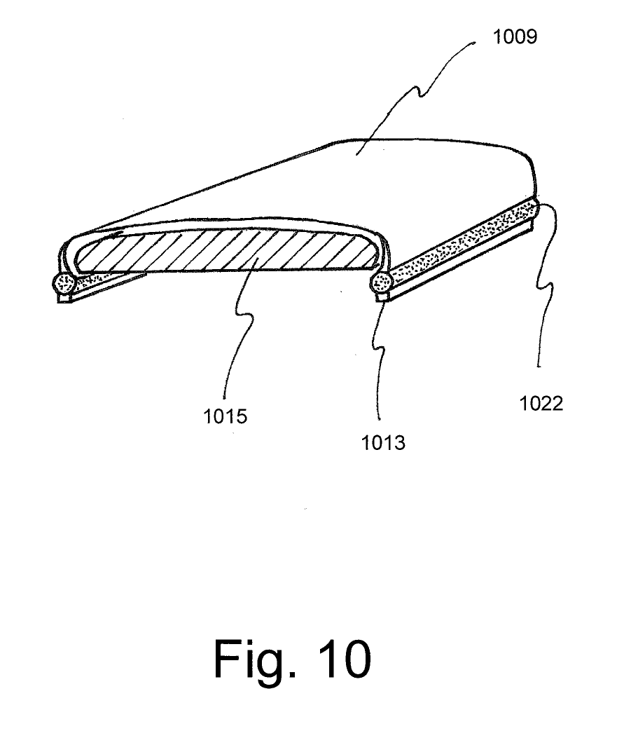

FIG. 10 is an illustration of a sleeve or case that will convert a device that does not meet any preferred embodiments of the present invention into a device that does. The original device 1015 that does not meet any preferred embodiments of the present invention has an accelerometer, but is too rigid for pushing or tapping to change the orientation of the accelerometer in the device. A case is constructed of a rigid housing 1009 with a compressible gasket 1022 between the housing and the bottom surface 1013 of the case. (When the case is set down on an immovable surface, the portion of the case that rests on the immovable surface is 1013.) When the device 1015 is slipped into the case as shown in FIG. 10, pushing down on the top of the case 1009 will compress the gasket 1022 in the same manner as shown in FIG. 3A, FIG. 3B, FIG. 4A, and FIG. 4B. An artisan can then program the device 1015 to use the change in orientation of its accelerometer for control and switching purposes as taught herein.

In an alternative embodiment (not shown), the original device 1015 that does not meet any preferred embodiments of the present invention either does not have an accelerometer, or has an accelerometer that cannot be used (for whatever reason) to provide the signals necessary to produce a switch signal. In this alternative embodiment (not shown), an accelerometer similar to the one shown in FIG. 3B is attached to the upper portion of the rigid housing 1009 so that it moves in the same manner as the accelerometer 103 in FIG. 3B when a user presses down on the rigid housing 1009 and the case is resting on an immovable surface. The accelerometer communicates its signal, such as via Bluetooth, to the device 1015 for use by the device 1015 in generating switch signals.

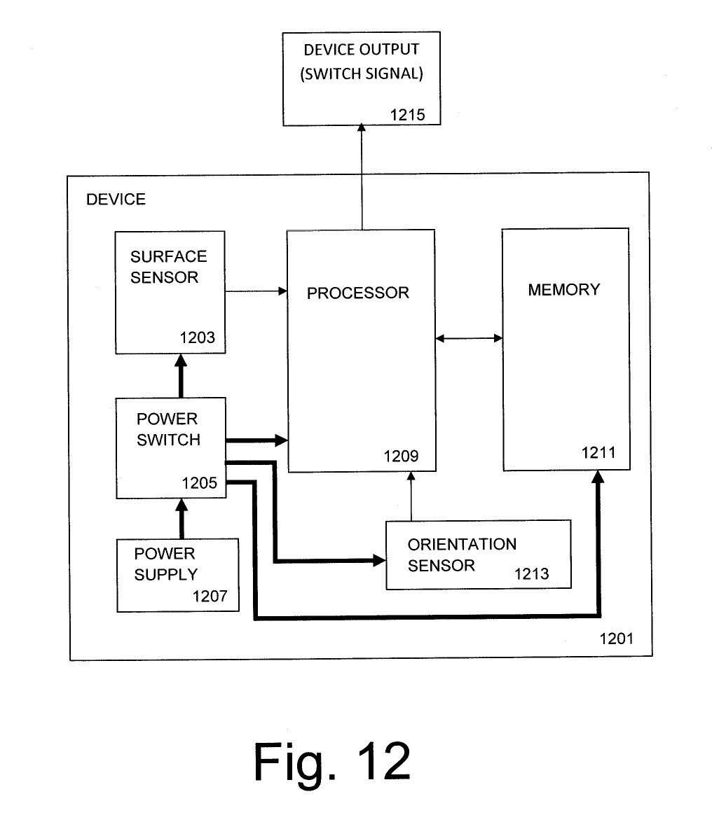

In an alternative embodiment (not shown), the case of FIG. 10 includes all of the electronic components shown in FIG. 12 and can communicate the switch signal 1215 to the device 1015 for use by the device 1015.

In an alternate embodiment, the gasket 1022 is replaced by a kink, crimp, or deformation of the rigid surface, an example of which is shown as 501 in FIG. 5A. In an alternate embodiment, the gasket 1022 is replaced by a compound curve or deformation of the rigid surface, an example of which is shown as 505 in FIG. 5C. In an alternate embodiment, the gasket 1022 the bottom surface of the gasket becomes the bottom surface of the case, in similar manner as shown in 509 of FIG. 5D. In an alternate embodiment, the gasket 1022 is replaced by a spring, in similar manner as shown in 503 of FIG. 5B.

In an alternate embodiment, the case completely covers the “top” and all four sides of the device, 1015. In an alternate embodiment, the case only covers portions of the “top” and the sides of the device. In an alternate embodiment, the bottom surface of the case 1013 forms one continuous surface. In an alternate embodiment, the bottom of the surface of the case 1013 is comprised of multiple separated segments. In an alternate embodiment, the case is not open on the “bottom” as shown in FIG. 10, but encloses that side of the encased device 1015.

The outer surface of the rigid housing 1009 may have portions that define at least two different regions (not shown in FIG. 10), wherein each region is associated with a respective switch signal, in the same manner as shown in FIG. 8 and FIG. 9.

Referring again to FIG. 5B and FIG. 5D, these embodiments can be characterized as having a housing 109 and a compressible portion (503 and 113 in FIG. 5B, and 509 and 113 in FIG. 5D), wherein an upper surface of the compressible portion is fixedly attached to the lower surface of the housing. In these embodiments, the surface sensor (not shown) may detect either that the bottom surface of the compressible portion is touching an external surface, or that a lower surface of the housing is in close proximity to an external surface. In this manner, it would not be necessary to embed the surface sensor into the compressible portion. For example, in one embodiment of FIG. 5D, the compressible portion, including the upper surface and bottom surface, is formed entirely from the compressible material, and thus the surface sensor needs to be placed on a lower surface of the housing. Likewise, it may be difficult to embed surface sensors into the bottom surface 113 in FIG. 5B, and thus the surface sensor may be placed on a lower surface of the housing 109.

The description has so far focused on the physical aspects of the device and of the user's interaction with it. FIG. 12 is a schematic diagram of hardware elements of the device. Some of the hardware devices include corresponding software for processing signals, as is well-known in the art. The device 1201 contains an orientation sensor 1213 to sense change in the orientation of the upper portion of the device, shown as 109 in FIG. 1B. This upper portion of the device, 109 in FIG. 1B, is also shown as 109 in FIG. 3A, FIG. 3B, FIG. 4A, FIG. 4B, FIG. 5A, FIG. 5B, FIG. 5C, FIG. 5D, FIG. 6A, and FIG. 6B, as well as 709 in FIG. 7, FIG. 8, and FIGS. 9, and 1009 in FIG. 10. The orientation sensor, 1213, is also shown as 103 in FIG. 1B, FIG. 3A, FIG. 3B, FIG. 4A, FIG. 4B, FIG. 5A, FIG. 5B, FIG. 5C, FIG. 5D, FIG. 6A, and FIG. 6B.

The orientation sensor 1213 sends output to a processor 1209 which performs calculations. Those calculations may require information retrieved from memory 1211 and the results of those calculations may be stored in memory 1211. Memory may be RAM, ROM, hard disk, flash drive, or any of the other means of electronic memory known to artisans knowledgeable in the art.

The device also include a surface sensor 1203 which detects when the lower portion of the device 113 in FIG. 3A, is placed against a stable or immovable surface 201 in FIG. 3A. The lower portion of the device shown as 113 in FIG. 3A, is also shown as 113 in FIG. 1B, FIG. 3B, FIG. 4A, FIG. 4B, FIG. 5A, FIG. 5B, FIG. 5C, and FIGS. 50) and 1009 (in FIG. 10). The immovable surface 201 in FIG. 3A, is also shown as 201 in FIG. 3B, FIG. 4A, FIG. 4B, FIG. 5A, FIG. 5B, FIG. 5C, and FIG. 50.

The surface sensor 1203 sends output to the processor 1209.

The device 1201 including its processor 1209, surface sensor 1203, orientation sensor 1213, and memory 1211, are powered by electrical current from a power supply, 1207. In a preferred embodiment the power supply 1207 is a battery inside the device 1201. In an alternative embodiment the power supply 1207 is outside the device (not pictured). In a preferred embodiment, electrical current to the device is controlled by a power switch 1205 to turn the device on and off. In an alternative embodiment, the power is always on, and the power switch is eliminated. In another alternative embodiment, the power switch is combined with the surface sensor. In another alternative embodiment, the power switch 1205 does not control power to the processor 1209 or memory 1211, but rather only controls power to the surface sensor 1203 and orientation sensor 1213. In an alternate embodiment, the power switch is replaced or supplemented by a switch that permits the device to receive output from the surface sensor and orientation sensor. In a preferred embodiment, the processor 1209 is dedicated solely to the functions of this device 1201. In an alternate embodiment, the processor 1209 is also used for other functions incorporated in the housing. An example is a smartphone where the processor 1209 is not only processing input from various sensors, but also routing phone calls. In a preferred embodiment, the memory 1211 is dedicated to the functions of this device 1201. In an alternate embodiment, the memory is used as well for other functions incorporated in the housing. An example is a smartphone where the memory is not only used to store input from the processor but also phone numbers.

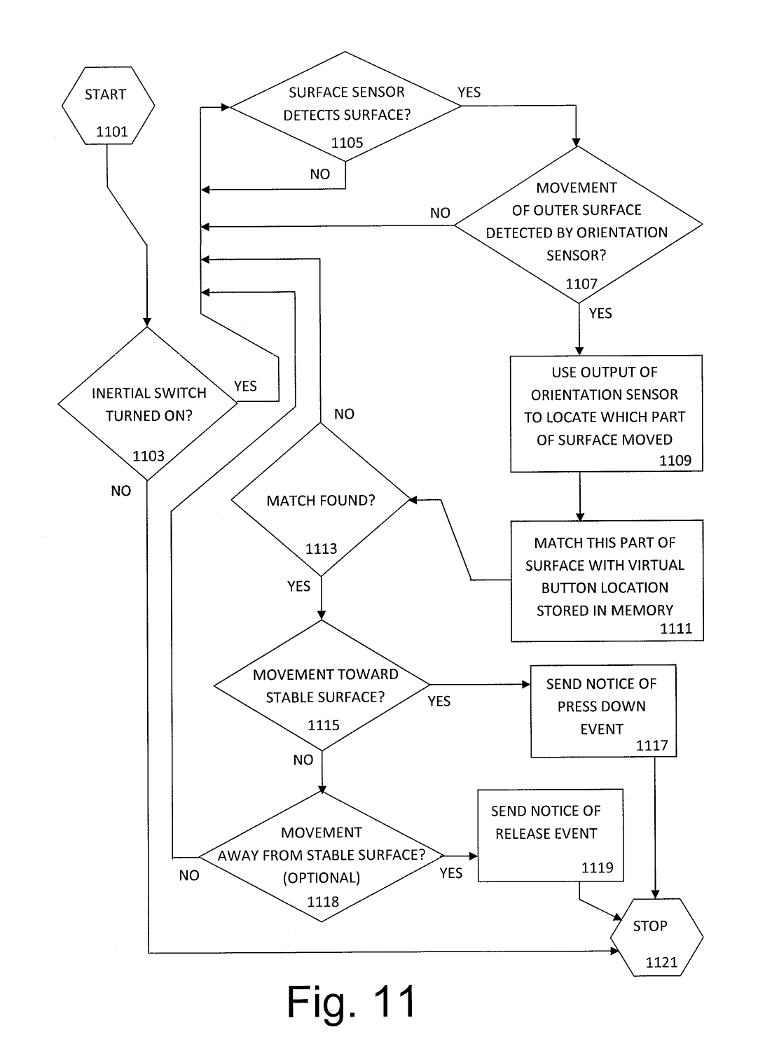

The outputs from the surface sensor 1203 and the orientation sensor 1213 are processed by the processor 1209, as more fully described in the flow chart in FIG. 11. As described above, the user interacts with the device 1201 when it is placed on an immovable surface (e.g. surface 201 of FIG. 3B, FIG. 4A, and FIG. 4B as detected by surface sensor 1203) by pressing an object or a finger (as in 203 of FIG. 3, FIG. 4A, and FIG. 4B) against parts of the outer surface of the upper portion of the device (e.g. 109 in FIG. 3B, FIG. 4A, and FIG. 4B), or by releasing the pressure of that object or finger. This press or release will affect the orientation sensor 1213 as shown in FIG. 3A, FIG. 3B, FIG. 4A, and FIG. 4B. When the processor 1213 determines that a switch event (e.g., a press or a release) has occurred (again see FIG. 11), it sends a switch signal as output 1215.

Consider now the flow chart in FIG. 11. At the start of use of the device (1101), if the inertial switch in the device is turned on (1103) (per power switch 1205 in FIG. 12), this process proceeds to consider whether the surface sensor (per surface sensor 1203 in FIG. 12) detects a surface (1105). However, if at this point in the flow chart (1103) the inertial switch is turned off (per power switch 1205 in FIG. 12), this ends the process at stop (1121).

Some switching devices are always turned on. For example, a computer mouse attached to a desktop computer via a USB cable receives power from that cable and is turned on as long as the computer is turned on and the mouse is plugged into the computer. In contrast, some switching devices must be explicitly turned on, either automatically or by the user. For example, a wireless mouse is battery powered. Some wireless mice automatically turn off switching functions when placed in a charging cradle in order to speed the recharging process. Some mice have a manual on/off switch to conserve battery life. This on/off switch also prevents the mouse from sending out false switch signals when not in use, such as while the user transports the mouse in his or her pocket. Some devices have a variety sensors (including, but not limited to, force sensors, orientation sensors, photoelectric sensors, and proximity sensors) to automatically determine when the device is not being used (such as when it is being stored or transported). Some of these devices use these sensors to automatically turn the device off when the device is not being used. Some devices use these sensors to automatically turn the device on when it is in a position to be used. In some multi-purpose, multi-processing, and multi-application devices, turning a process (or application) on or off is equivalent to turning on or off a single purpose device that only performs that process (or application). The ways in which false positive switch signals can be suppressed or filtered out when the device is being transported are well known to those skilled in the art, and thus are not described in further detail.

Returning to the flow chart in FIG. 11, and, considering that the inertial switch is turned on (1103) (per power switch 1205 in FIG. 12), the device then proceeds to consider whether the surface sensor (1203 in FIG. 12) detects that the device is placed on a stable surface (1105). If the surface sensor (1203 in FIG. 12) detects a stable surface (1105), then the device proceeds to consider whether the orientation sensor (1213 in FIG. 12) detects movement (1107). However, if the surface sensor (1203 in FIG. 12) does not detect that the device is on a stable surface (1105), then the device recursively waits at step 1105 until such surface is detected.

The movement detection must be “significant,” meaning that it exceeds a noise or threshold level so that accidental trivial movement or a brief noise signal is not interpreted as movement. The noise or threshold level will depend upon many factors well-understood to an artisan in sensor detection. The noise or threshold level may be calibrated to correspond to movement associated with a predetermined percentage compression of the compressible material, such as at least 10%. As described herein, “movement” thus means that the movement exceeds the noise or threshold level, and thus is significant.

The surface sensor (1203 in FIG. 12) may be comprised of one or more other sensors, including, but not limited to, one or more proximity sensors (sensing that the bottom surface of the device is on another object), one or more photoelectric sensors (sensing that the bottom surface of the device is covering or covered by another object preventing light from reaching the sensor), one or more force sensors (sensing that the bottom surface of the device is being pressed against another object), one or more optical or imaging sensors, and one or more accelerometers (sensing that the device is not in free fall, but held steady with no fluctuation against the pull of gravity). The intended use of the device and the environment in which it is to be used determine which sensor or sensor array is most effective. For example, a desktop computer mouse which employs the present invention and which is only used on the surface of a desk, may use the lack of input to its position detector (whether a ball or an optical detector) to determine that the mouse is on or not on a stable surface. Surface sensors are well-known in the art. See, for example, U.S. Pat. No. 5,731,582 (West), incorporated herein by reference. The surface sensor and the on/off switch may be combined.

Returning to the flow chart in FIG. 11, and considering that the surface sensor (1203 in FIG. 12) detected that the device is on a stable surface (1105) and is considering whether the orientation sensor (1213 in FIG. 12) detects movement of the outer surface of the upper portion of the device (1107). If no movement is detected at 1107, the device recursively returns to 1105 to check the surface sensor.

If movement is detected at 1107 by the orientation sensor (1213 in FIG. 12), then the output of the orientations sensor is used by the processor (1209 in FIG. 12) to locate which part of the surface moved (1109). For example as disclosed above, the output of the orientation sensor indicates if a corner of the device is pushed and which one. See, for example, FIG. 8, items numbered 801, 805, 817, and 813, and FIG. 9, items 901, 903, 905, and 907. The output of the orientation sensor also indicates if a corner has not been pushed, but rather if a region between the corners has been pushed and which one, see FIG. 8, items 803, 811, 815, and 807. The output of the orientation sensor also indicates if instead, the device has been pushed in the center, FIG. 8, item 809.

The processor (1209 in FIG. 12) will attempt to match the location which the orientation sensor determined has been moved (1109) to the location of a virtual button (1111). It does this by comparing the location where movement occurred to the locations of virtual buttons stored in memory (1211 in FIG. 12). If a match is found at step 1113, the device determines the direction of the movement (1115). If no match is found, at step 1113, it means that the device has been pushed or moved on a portion of the surface that is not a virtual button, and no switch signal is to be generated. In that case, the process goes back to 1105 to see if the surface sensor still detects that the device is on a stable surface.

Otherwise, if a match is found at 1113, the device again considers the output of the orientation sensor (1213 in FIG. 12) to see whether the movement was towards the stable surface (201 in FIG. 3B, FIG. 4A, and FIG. 4B), being step 1115. This is the same as detecting that the movement was towards the lower portion of device housing (113 in FIG. 3B, FIG. 4A, and FIG. 4B), which is the portion resting on the stable surface 201. If the movement is towards the stable surface 201, (or the lower portion of the housing 113), the processor (1209 in FIG. 12) sends a notice of a press down event for the matched virtual button at step 1117, and the process stops, 1121. If at step 1115, the movement is not toward the stable surface, the device asks if the movement is away from the stable surface, 1118. If yes, the processor (1209 in FIG. 12) sends a notice of a pressure release event for the matched virtual button at step 1119, and the process stops, 1121. If at step 1115, the movement is not away from the stable surface, then the process returns to step 1105.

In an alternate embodiment, where the change in orientation which identifies the virtual button can only be towards or away from the stable surface, the step 1118 is eliminated. Then after 1115, if the movement is not towards the stable surface, it must be away from the stable surface, so the processor 1209 sends a notice of a pressure release event (1119) for the matched virtual button, and the process stops (1121).

FIG. 11 and FIG. 12 have a plurality of different permutations. In one permutation, the outer surface of the upper portion defines at least two different regions, each region being associated with a respective switch signal. The steps 1109 and 1111 of FIG. 11 and pre-stored mapping information in the memory 1211 of FIG. 12 is used to detect which region was pressed. In another permutation, a portion of the outer surface of the upper portion may define only one region (e.g., one virtual button). However, the memory 1211 still maintains a mapping of the region on the outer surface of the upper portion so that it can be detected whether the user actually pressed on the region, or pressed outside of the region. Both types of pressing will generate an accelerometer signal, but only pressing in the region defined by the virtual button should cause the output of a switch signal.

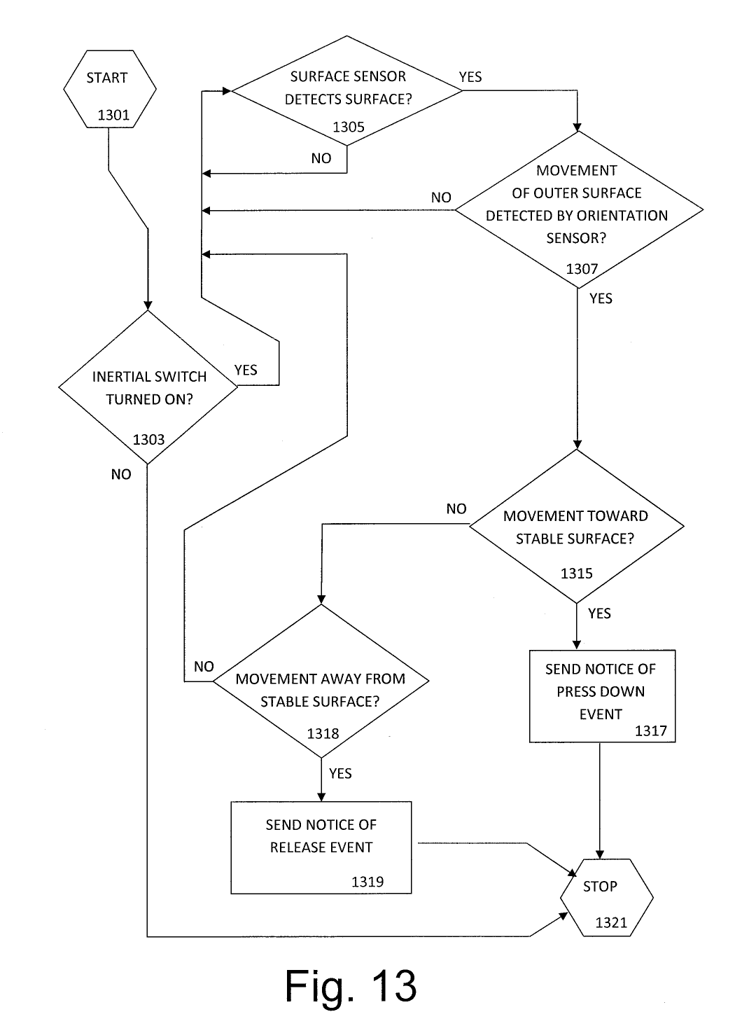

FIG. 13 is a flow chart for another preferred embodiment wherein no regions are defined, and any significant pressing down and releasing event that occurs while the device is on a stable surface causes the output of a switch signal. For example, a significant pressing on either the middle or side of the device, such as shown in FIG. 3B or FIG. 4B, followed by a releasing, would cause the same output. This embodiment does not require any mapping of portions of the outer surface to define different regions, and thus steps 1109, 1111 and 1113 of FIG. 11 and pre-stored mapping information in the memory 1211 of FIG. 12 are not required.

Consider now the flow chart in FIG. 13. At the start of use of the device (1301), if the inertial switch in the device is turned on (1303) (via power switch 1205 in FIG. 12), this process proceeds to consider whether the surface sensor (via surface sensor 1203 in FIG. 12) detects a surface (1305). However, if at this point in the flow chart (1303) the inertial switch is turned off (via power switch 1205 in FIG. 12), this ends the process at stop (1321).

Returning to the flow chart in FIG. 13, and, considering that the inertial switch is turned on (1303), the device then proceeds to consider whether the surface sensor detects that the device is placed on a stable surface (1305). If the surface sensor detects a stable surface (1305), then the device proceeds to consider whether the orientation sensor (1213 in FIG. 12) detects movement (1307). However, if the surface sensor does not detect that the device is on a stable surface (1305), then the device recursively waits at step 1305 until such surface is detected.

Returning to the flow chart in FIG. 13, the surface sensor detects whether the device is on a stable surface (1305) and whether the orientation sensor detects movement of the outer surface of the upper portion of the device (1307). If no movement is detected at 1307, the device recursively returns to 1305 to check the surface sensor.

If movement is detected at 1307 by the orientation sensor, then the device again considers the output of the orientation sensor to see whether the movement of the outer surface (109 in FIG. 3B, FIG. 4A, and FIG. 4B) was towards the stable surface (201 in FIG. 3B, FIG. 4A, and FIG. 4B), being step 1315. This is the same as detecting that the movement was towards the lower portion of device housing (113 in FIG. 3B, FIG. 4A, and FIG. 4B), which is the portion resting on the stable surface 201. If the movement is towards the stable surface 201, (or the lower portion of the housing 113), the processor (1209 in FIG. 12) sends a notice of a press down event at step 1317, and the process stops (1321). Otherwise, the device checks if the movement is away from the stable surface (1318). If not, the process recursively returns to step 1305 to check the surface sensor. If yes, then the device sends a notice of release event at step 1319, and the process stops (1321).

In view of the discussion above, the devices can be defined by at least the following general structural permutations:

1. A fully self-contained apparatus that includes all of the electronic parts necessary for operation (e.g., elements in FIG. 12). In one version, the apparatus outputs a switch signal 1215 which is used directly to control some functionality of an external device. In another version, the apparatus may be a case that accepts another electronic device, such as a smartphone. While the form factor for this version is described with respect to FIG. 10, other form factors are within the scope of the present invention, including the form factors shown in FIGS. 1B, FIGS. 5A-5D, FIGS. 6A-6B and FIGS. 7-9. That is, while each of these figures show embodiments of the invention that output a switch signal 1215, each of these embodiments may be adapted to act as a case to receive an electronic device, such as a smartphone, that may receive the switch signal 1215 and make use of the signal in an application running on the smartphone. In this manner, the functionality of an electronic device, such as a smartphone, is extended to provide new switch functions that the smartphone may be unable to perform by itself.

2. An apparatus that has no electronic parts, and includes a receiving portion for receiving and holding an electronic device that includes all of the electronic parts necessary for operation (e.g., elements in FIG. 12), such as shown in FIG. 10.

3. An apparatus that has a three-dimensional orientation sensor (e.g., an accelerometer) and related communication circuitry as its only electronic parts, and includes a receiving portion for receiving and holding the electronic device, such as shown in FIG. 10. The orientation sensor resides in the upper portion of the apparatus. The communication circuitry transmits the sensor output to circuitry in the electronic device, such as via Bluetooth. The sensor may also need to include circuitry to filter, normalize or condition its output so that it is in a suitable form for transmission by the communication circuitry and subsequent processing by processor logic in the processor of the electronic device. In an alternative version, the apparatus may also include the surface sensor described above, along with appropriate circuitry to filter, normalize or condition the surface sensor output so that it is also in a suitable form for transmission by the communication circuitry and subsequent processing by processor logic in the processor of the electronic device.

These embodiments may be generally characterized as having at least the following elements:

1. An upper portion including (i) an outer surface having portions that define at least two different regions, wherein at least one of the different regions has a switch function, and (ii) a three-dimensional orientation sensor that generates three-dimensional orientation signals in response to movement of the upper portion.

2. A lower portion having a bottom surface adapted to be placed against an immovable surface.

3. A surface sensor that detects whether the bottom surface is touching an external surface and outputs a signal indicating whether the bottom surface is touching an external surface.

4. Compressible material which becomes deformed under pressure. The compressible material is disposed between the upper portion and the lower portion.

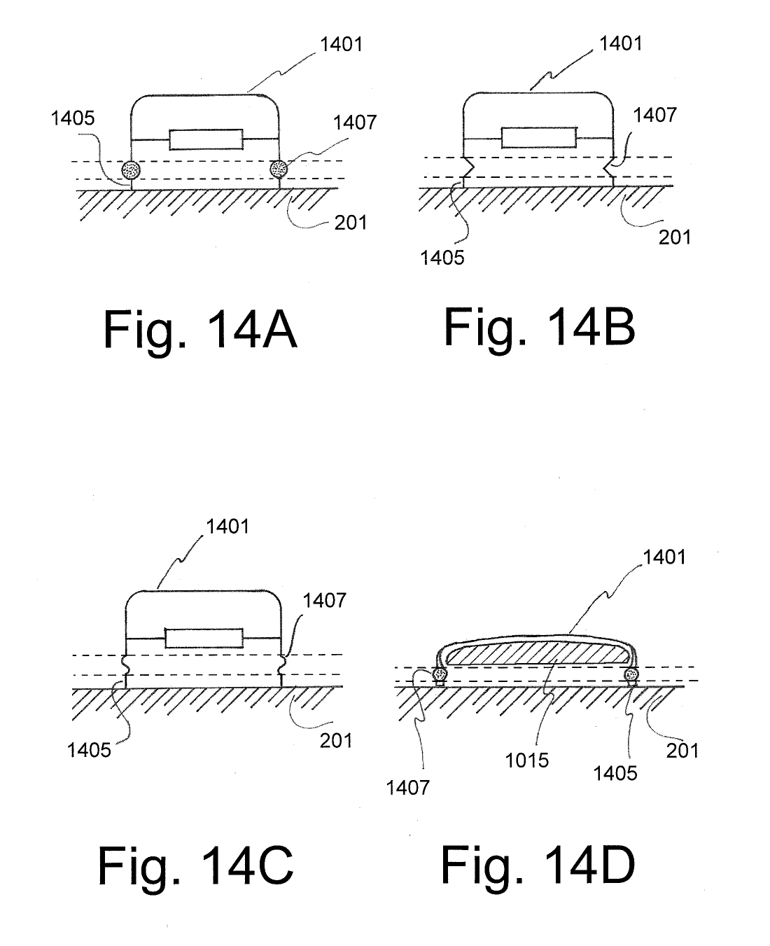

FIGS. 14A-14D further define where the upper portions and lower portions are located in certain embodiments of the present invention. In each of these figures, the upper portion is the portion above the upper dashed line, and the lower portion is the portion below the lower dashed line. In each of these figures, the compressible material is disposed between the upper portion and the lower portion. These figures correspond to previously described figures, and thus are not described in further detail herein, other than to identify their respective numbers.

FIG. 14A corresponds to FIG. 3A, wherein 1401 is the upper part, 1405 is the lower part, 1407 is the compressible material, and 201 is the immovable surface 201.

FIG. 14B corresponds to FIG. 5A, wherein 1401 is the upper part, 1405 is the lower part, 1407 is the compressible material, and 201 is the immovable surface 201.

FIG. 14C corresponds to FIG. 5C, wherein 1401 is the upper part, 1405 is the lower part, 1407 is the compressible material, and 201 is the immovable surface 201.

FIG. 14D corresponds to FIG. 10, wherein 1401 is the upper part, 1405 is the lower part, 1407 is the compressible material, 201 is the immovable surface 201, and 1015 is the device.

The present invention may be implemented with any combination of hardware and software. If implemented as a computer-implemented apparatus, the present invention is implemented using means for performing all of the steps and functions described above.

Software code for implementing FIG. 11 and FIG. 13 can be executed on any suitable processor or collection of processors, whether provided in a single computer or distributed among multiple computers. The software code can also be included in an article of manufacture (e.g., one or more computer program products) having, for instance, computer readable storage media. The storage media has computer readable program code stored therein that is encoded with instructions for execution by a processor for providing and facilitating the mechanisms of the present invention. The article of manufacture can be included as part of a computer system or sold separately.

The storage media can be any known media, such as computer memory, one or more floppy discs, compact discs, optical discs, magnetic tapes, flash memories, circuit configurations in Field Programmable Gate Arrays or other semiconductor devices, or other tangible computer storage medium. The storage media can be transportable, such that the program or programs stored thereon can be loaded onto one or more different computers or other processors to implement various aspects of the present invention as discussed above.

The various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

The terms “program” or “software” are used herein in a generic sense to refer to any type of computer code or set of computer-executable instructions that can be employed to program a computer or other processor to implement various aspects of the present invention as discussed above. The computer program need not reside on a single computer or processor, but may be distributed in a modular fashion amongst a number of different computers or processors to implement various aspects of the present invention.

Computer-executable instructions may be in many forms, such as program modules, executed by one or more computers or other devices. Generally, program modules include routines, programs, objects, components, data structures, and the like, that perform particular tasks or implement particular abstract data types. The functionality of the program modules may be combined or distributed as desired in various embodiments.

Preferred embodiments of the present invention may be implemented as methods, of which examples have been provided. The acts performed as part of the methods may be ordered in any suitable way. Accordingly, embodiments may be constructed in which acts are performed in an order different than illustrated, which may include performing some acts simultaneously, even though such acts are shown as being sequentially performed in illustrative embodiments.

While the present invention has been particularly shown and described with reference to one preferred embodiment thereof, it will be understood by those skilled in the art that various alterations in form and detail may be made therein without departing from the spirit and scope of the present invention.

What is claimed is:

1. An apparatus configured to provide switch signals, the apparatus comprising:
(a) an upper portion including:
(i) an outer surface having portions that define at least two different regions, wherein at least one of the different regions has a switch function, and
(ii) a three-dimensional orientation sensor that generates three-dimensional orientation signals in response to movement of the upper portion;
(b) a lower portion having a bottom surface adapted to be placed against an immovable surface;
(c) a surface sensor that detects whether the bottom surface is touching an external surface and outputs a signal indicating whether the bottom surface is touching an external surface;
(d) compressible material which becomes deformed under pressure, the compressible material being disposed between the upper portion and the lower portion, the compressible material allowing the upper portion to move towards the lower portion when the outer surface of the upper portion is pressed and the lower portion is placed against the immovable surface;
(e) memory that electronically stores information regarding the portions of the outer surface that define the at least one region having a switch function; and
(f) a processor including processor logic that:
(i) receives the orientation signals from the orientation sensor and the signal from the surface sensor,
(ii) uses the electronically stored information in the memory, the orientation signals, and the surface sensor signal to detect whether a region having a switch function was pressed and the bottom surface is touching an external surface, and
(iii) outputs a first switch signal indicating the region that was pressed if it is detected that a region having a switch function was pressed and the bottom surface is touching an external surface.

2. The apparatus of claim 1 wherein there are a plurality of different regions that have switch functions, and wherein the memory electronically stores information regarding the portions of the outer surface that define the plurality of different regions that have switch functions.

3. The apparatus of claim 2 wherein the plurality of different regions define corner regions, thereby allowing the apparatus to provide switch signals if a corner region is pressed and it is detected that the bottom surface is touching an external surface.

4. The apparatus of claim 2 wherein the entire outer surface is defined by the plurality of different regions so that a first switch signal will always be output if any region is pressed and it is detected that the bottom surface is touching an external surface.

5. The apparatus of claim 1 wherein only one region is defined as having a switch function, and thus pressing on any regions other than the one region defined as having a switch function does not result in outputting of a first switch signal.

6. The apparatus of claim 1 wherein the compressible material returns to an undeformed state when the upper portion is no longer being pressed, and wherein the processor logic of the processor further:
(iv) outputs a second switch signal subsequent to outputting the first switch signal indicating that the upper portion is no longer being pressed, the second switch signal being associated with the same region that was pressed and that caused the first switch signal to be output.

7. The apparatus of claim 1 wherein the three-dimensional orientation sensor is an accelerometer.

8. The apparatus of claim 1 wherein the apparatus is a case for an electronic device.

9. The apparatus of claim 1 wherein the compressible material is a gasket.

10. An apparatus configured to provide switch signals, the apparatus comprising:
(a) an upper portion including:
(i) an outer surface, and
(ii) a three-dimensional orientation sensor that generates three-dimensional orientation signals in response to movement of the upper portion;
(b) a lower portion having a bottom surface adapted to be placed against an immovable surface;
(c) a surface sensor that detects whether the bottom surface is touching an external surface and outputs a signal indicating whether the bottom surface is touching an external surface;
(d) compressible material which becomes deformed under pressure and returns to an undeformed state when not under pressure, the compressible material being disposed between the upper portion and the lower portion, the compressible material allowing the upper portion to move towards the lower portion when the outer surface of the upper portion is pressed and the lower portion is placed against the immovable surface; and
(e) a processor including processor logic that:
(i) receives the orientation signals from the orientation sensor and the signal from the surface sensor,
(ii) uses the orientation signals, and the surface sensor signal to detect whether the upper portion was moved towards the lower portion and the bottom surface is touching an external surface,
(iii) outputs a first switch signal indicating that the upper portion was pressed if it is detected that the upper portion was moved towards the lower portion and the bottom surface is touching an external surface, and
(iv) outputs a second switch signal subsequent to outputting the first switch signal indicating that the upper portion is no longer being pressed.

11. The apparatus of claim 10 wherein the three-dimensional orientation sensor is an accelerometer.

12. The apparatus of claim 10 wherein the compressible material is a gasket.

13. An apparatus for encasing an electronic device and configured to provide movement to be detected by circuitry in the electronic device, the apparatus comprising:
(a) an upper portion including:
(i) an outer surface having portions that define at least two different regions, wherein at least one of the different regions has a switch function, and
(ii) a receiving portion for receiving and holding the electronic device;
(b) a lower portion having a bottom surface adapted to be placed against an immovable surface; and
(c) compressible material which becomes deformed under pressure, the compressible material being disposed between the upper portion and the lower portion, the compressible material allowing the upper portion to move towards the lower portion when the outer surface of the upper portion is pressed and the lower portion is placed against the immovable surface.

14. The apparatus of claim 13 wherein the upper portion further includes:
(iii) a three-dimensional orientation sensor that generates three-dimensional orientation signals in response to movement of the upper portion, and
(iv) communication circuitry for transmitting the signals to the circuitry in the electronic device.

15. The apparatus of claim 14 wherein the three-dimensional orientation sensor is an accelerometer.

16. The apparatus of claim 13 wherein the compressible material is a gasket.

17. An apparatus configured to provide switch signals, the apparatus comprising:
(a) housing including:
(i) an outer surface having portions that define at least two different regions, wherein at least one of the different regions has a switch function,
(ii) a lower surface, and
(ii) a three-dimensional orientation sensor that generates three-dimensional orientation signals in response to movement of the housing;
(b) a compressible portion including:
(i) an upper surface fixedly attached to the lower surface of the housing,
(ii) a bottom surface adapted to be placed against an immovable surface,
(iii) compressible material which becomes deformed under pressure, the compressible material allowing the housing to move towards the immovable surface when the outer surface of the housing is pressed and the bottom surface of the compressible portion is placed against the immovable surface;
(c) a surface sensor that detects whether (i) the bottom surface of the compressible portion is touching an external surface, or (ii) the lower surface of the housing is in close proximity to an external surface, and outputs a signal indicating whether (i) the bottom surface of the compressible portion is touching an external surface, or (ii) the lower surface of the housing is in close proximity to an external surface;
(d) memory that electronically stores information regarding the portions of the outer surface that define the at least one region having a switch function; and
(e) a processor including processor logic that:
(i) receives the orientation signals from the orientation sensor and the signal from the surface sensor,
(ii) uses the electronically stored information in the memory, the orientation signals, and the surface sensor signals to detect whether a region having a switch function was pressed, and whether (i) the bottom surface of the compressible portion is touching an external surface, or (ii) the lower surface of the housing is in close proximity to an external surface, and
(iii) outputs a first switch signal indicating the region that was pressed if it is detected that a region having a switch function was pressed, and (i) the bottom surface of the compressible portion is touching an external surface, or (ii) the lower surface of the housing is in close proximity to an external surface.

18. The apparatus of claim 17 wherein there are a plurality of different regions that have switch functions, and wherein the memory electronically stores information regarding the portions of the outer surface that define the plurality of different regions that have switch functions.

19. The apparatus of claim 17 wherein only one region is defined as having a switch function, and thus pressing on any regions other than the one region defined as having a switch function does not result in outputting of a first switch signal.

20. The apparatus of claim 17 wherein the three-dimensional orientation sensor is an accelerometer.

21. The apparatus of claim 17 wherein the compressible material is a spring.

22. The apparatus of claim 17 wherein the compressible material is a gasket.

23. The apparatus of claim 17 wherein the compressible portion, including the upper surface and bottom surface, is formed entirely from the compressible material.
